(19) United States
(12) Patent Application Publication
(10) Pub. No.: US 2025/0268020 A1
(43) Pub. Date: Aug. 21, 2025

(54) MANUFACTURING METHOD OF DISPLAY DEVICE

(71) Applicant: Samsung Display Co., LTD., Yongin-si (KR)

(72) Inventor: DONGHA LEE, Yongin-si (KR)

(21) Appl. No.: 18/957,047

(22) Filed: Nov. 22, 2024

(30) Foreign Application Priority Data
Feb. 20, 2024 (KR) 10-2024-0024242

(51) Int. Cl. H10K 59/12; H10K 50/115; H10K 71/12

(52) U.S. Cl. CPC H10K 59/1201; H10K 71/12; H10K 50/115

(57) ABSTRACT

A method of manufacturing a display device includes forming a plurality of first electrodes on a substrate, forming a first hole injection layer, a second hole injection layer, and a third hole injection layer on each of the plurality of first electrodes, forming a second hole transport layer and a third hole transport layer on the second hole injection layer and the third hole injection layer, forming a second light emitting layer on the second hole transport layer and the third hole transport layer, and forming a third light emitting layer, and after the second light emitting layer and the third light emitting layer are formed, sequentially forming a first hole transport layer and a first light emitting layer on the first hole injection layer, each of the second and third light emitting layers includes a quantum dot, and the first light emitting layer includes an organic material.

### CROSS-REFERENCE TO RELATED APPLICATION

The present application claims priority to and the benefit of Korean Patent Application No. 10-2024-0024242, filed on Feb. 20, 2024, in the Korean Intellectual Property Office, the entire content of which is incorporated herein by reference.

### BACKGROUND

### 1. Field

This present disclosure relates to a method of manufacturing a display device.

### 2. Description of the Related Art

A light emitting element is a device in which holes supplied by (provided from) an anode and electrons supplied by (provided from) a cathode combine to form excitons in a light emitting layer formed between the anode and the cathode. Light is emitted when the excitons transition from an excited state to a ground state.

Light emitting elements have one or more suitable advantages or enhancements (i.e., these light-emitting elements offer several notable benefits) such as wide viewing angle, fast response speed, thinness, and/or low power consumption. Therefore, they are widely applied to one or more suitable electrical and electronic devices such as televisions, monitors, and/or mobile phones.

### SUMMARY

An aspect according to one or more embodiments is directed toward a method of manufacturing a display device with improved lifespan and reliability of a light emitting element.

A method of manufacturing a display device according to one or more embodiments includes forming a plurality of first electrodes on a substrate, forming a first hole injection layer, a second hole injection layer, and a third hole injection layer on a respective one of the plurality of first electrodes, forming a second hole transport layer and a third hole transport layer respectively on the second hole injection layer and the third hole injection layer, forming a second light emitting layer and a third light emitting layer respectively on the second hole transport layer and the third hole transport layer, and after the forming of the second light emitting layer and the third light emitting layer, sequentially forming a first hole transport layer and a first light emitting layer on the first hole injection layer, wherein each of the second light emitting layer and the third light emitting layer includes a quantum dot, and the first light emitting layer includes an organic material.

After the forming of the second light emitting layer and the third light emitting layer, the method may further include forming a second electron transport layer and a third electron transport layer respectively on the second light emitting layer and the third light emitting layer.

After the forming of the second electron transport layer and the third electron transport layer, the first hole transport layer and the first light emitting layer may be formed sequentially.

The method may further include forming a first electron transport layer on the first light emitting layer.

The display device includes a blue light emitting region overlapping with the first light emitting layer, a red light emitting region overlapping with the second light emitting layer, and a green light emitting region overlapping with the third light emitting layer, and the method may further include forming a partition arranged between adjacent light emitting regions selected from among the blue light emitting region, the red light emitting region, and the green light emitting region.

The first hole injection layer, the second hole injection layer, and the third hole injection layer may be spaced (e.g., separated) from each other with respect to the partition, and the first hole transport layer, the second hole transport layer, and the third hole transport layer may be spaced (e.g., separated) from each other with respect to the partition.

The method may further include forming a second electrode continuously positioned on the first emitting layer, the second emitting layer, and the third emitting layer.

The first light emitting layer may include an organic material, the second light emitting layer may include a first (e.g., red) quantum dot, and the third light emitting layer may include a second (e.g., green) quantum dot.

The second electron transport layer and the third electron transport layer may each include ZnMgO.

The first electron transport layer may include an organic electron transport material.

A method of manufacturing a display device according to one or more embodiments includes forming the plurality of first electrodes on a substrate, forming a first hole injection layer, a second hole injection layer, and a third hole injection layer on a respective one of the plurality of first electrodes, forming a first hole transport layer on the first hole injection layer, forming a first light emitting layer on the first hole transport layer, after the forming of the first light emitting layer, forming a second hole transport layer and a third hole transport layer respectively on the second hole injection layer and the third hole injection layer, and forming a second light emitting layer and a third light emitting layer respectively on the second hole transport layer and the third hole transport layer.

After the forming of the first light emitting layer, the method may further include forming a first electron transport layer on the first light emitting layer.

After the forming of the first electron transport layer, the second hole transport layer and the third hole transport layer may be formed.

The method may further include forming a second electron transport layer and a third electron transport layer respectively on the second light emitting layer and the third light emitting layer.

The method may further include forming a second electrode positioned contiguously on the first electron transport layer, the second electron transport layer, and the third electron transport layer.

The display device may include a blue light emitting region overlapping with the first light emitting layer, a red light emitting region overlapping with the second light emitting layer, and a green light emitting region overlapping with the third light emitting layer, and the method may further include forming a partition arranged between adjacent light emitting regions selected from among the blue light emitting region, the red light emitting region, and the green light emitting region.

The first hole injection layer, the second hole injection layer, and the third hole injection layer may be spaced (e.g., separated) from each other with respect to the partition, and the first hole transport layer, the second hole transport layer, and the third hole transport layer may be spaced (e.g., separated) from each other with respect to the partition.

The first light emitting layer may include an organic material, the second light emitting layer may include a first quantum dot, and the third light emitting layer may include a second quantum dot.

The second electron transport layer and the third electron transport layer may each include ZnMgO.

The first electron transport layer may include an organic electron transport material.

According to one or more embodiments, a method of manufacturing a display device with improved lifespan and reliability of a light emitting element can be provided.

### BRIEF DESCRIPTION OF THE DRAWINGS

The above and other aspects, features, and enhancements of certain embodiments of the present disclosure will be more apparent from the following description taken in conjunction with the accompanying drawings, in which:

FIG. 1 is a cross-sectional view of a display device according to one or more embodiments.

FIG. 2 is a flowchart of a method of manufacturing some components of a display device according to one or more embodiments.

FIG. 3 to FIG. 10 are cross-sectional views sequentially showing a manufacturing process of a display device according to one or more embodiments.

FIG. 11 is a flowchart of a method of manufacturing some components of a display device according to one or more embodiments.

FIG. 12 to FIG. 20 are cross-sectional views sequentially showing a manufacturing process of a display device according to one or more embodiments.

### DETAILED DESCRIPTION

Hereinafter, with reference to the accompanying drawings, one or more suitable embodiments of the present disclosure will be described in more detail so that those skilled in the art can easily implement the present disclosure. The present disclosure may be implemented in many different suitable forms and is not limited to one or more embodiments described herein.

In order to clearly explain the present disclosure, parts that are not relevant to the description are omitted (e.g., may not be provided), and substantially identical or similar components are assigned the same reference numerals throughout the specification.

In addition, the size and thickness of each component shown in the drawings are shown arbitrarily for convenience of explanation, so the present disclosure is not necessarily limited to that which is shown. In the drawing, the thickness may be enlarged to clearly show one or more suitable layers and regions. And in the drawings, for convenience of explanation, the thicknesses of some layers and regions may be exaggerated.

Additionally, if (e.g., when) a part of a layer, membrane, region, or plate is said to be “above” or “on” an other part, this includes not only cases where it is “directly above” the other part, but also cases where there is another part in between. In contrast, if (e.g., when) an element is referred to as being “directly on” another element, there are no intervening elements present. In addition, being “above” or “on” a reference portion refers to being located above or below the reference portion, and does not necessarily refer to being located “above” or “on” it in the direction opposite to gravity.

In addition, throughout the specification, if (e.g., when) a part is said to “include” a certain component, this refers to that it may further include other components rather than excluding other components, unless specifically stated to the contrary.

In addition, throughout the specification, if (e.g., when) reference is made to “on a plane,” this refers to if (e.g., when) the target portion is viewed from above, and if (e.g., when) reference is made to “in cross-section,” this refers to if (e.g., when) a cross section of the target portion is cut vertically and viewed from the side.

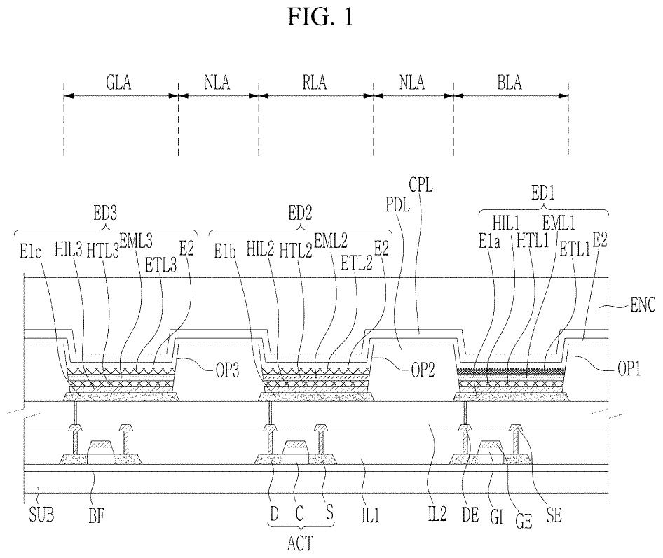

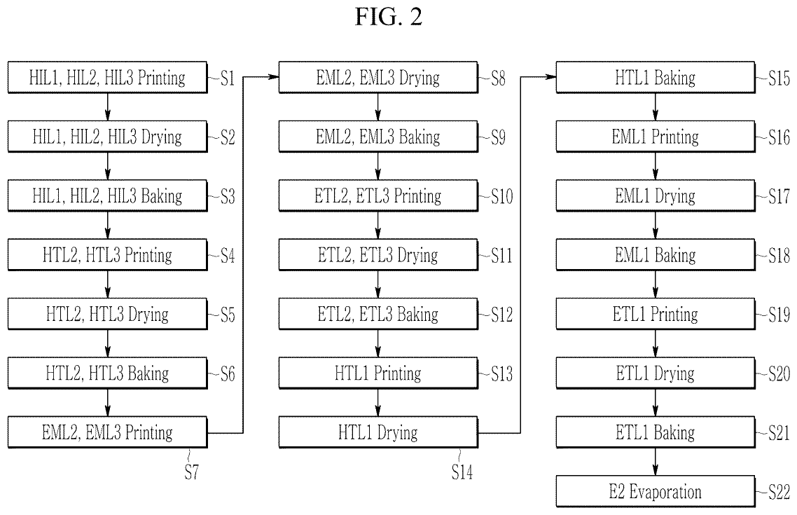

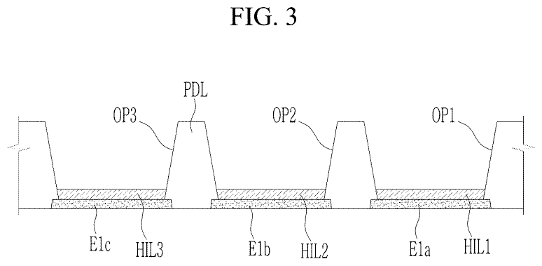

Hereinafter, a display device and a method of manufacturing the display device according to one or more embodiments will be described with reference to FIGS. 1 to 10. FIG. 1 is a cross-sectional view of a display device according to one or more embodiments, FIG. 2 is a flowchart of a method for manufacturing some components of a display device according to one or more embodiments, and FIGS. 3 to 10 are cross-sectional views sequentially illustrating the manufacturing process of a display device according to one or more embodiments.

Referring to FIG. 1, a display device according to one or more embodiments includes a red light emitting region RLA, a green light emission region GLA, and a blue light emission region BLA. A non-light emitting region NLA may be located between the red light emitting region RLA, the green light emitting region GLA, and the blue light emitting region BLA. That is, a non-light emitting region NLA may be located between two adjacent light emitting regions from among the red light emitting region RLA, the green light emitting region GLA, and the blue light emitting region BLA. Each light emitting region may correspond to a pixel. For example, the blue light emitting region BLA, the red light emitting region RLA, and the green light emitting region GLA may correspond to blue pixels, red pixels, and green pixels, respectively. The shape and arrangement of each of the red light emitting region RLA, the green light emitting region GLA, and the blue light emitting region BLA may be modified in one or more suitable ways.

A display device according to one or more embodiments includes a substrate SUB. The substrate SUB may include a flexible material such as a plastic (e.g., polymeric material) that can bend, fold, and/or roll, or may include a rigid substrate.

A buffer layer BF may be located on the substrate SUB. Depending on the embodiment, the buffer layer BF may not be provided. The buffer layer BF may include silicon nitride (SiNx), silicon oxide (SiO₂), or silicon oxynitride. The buffer layer BF is located between the substrate SUB and a semiconductor layer ACT, and improves the properties of the semiconductor layer ACT (polycrystalline silicon of the semiconductor layer ACT) by blocking impurities from the substrate SUB during the crystallization process to form polycrystalline silicon, and by providing a flat surface (e.g., flattening), the stress of the semiconductor layer ACT formed on the buffer layer BF can be alleviated.

The semiconductor layer ACT is located on the buffer layer BF. The semiconductor layer ACT may be made of polycrystalline silicon or an oxide semiconductor. The semiconductor layer ACT includes a channel region C, a source region S, and a drain region D. The source region S and drain region D are respectively arranged on both sides (e.g., opposite sides) of the channel region C.

The channel region C is an intrinsic semiconductor that is not doped with impurities, and the source region S and drain region D are impurity-doped semiconductors that are doped with conductive impurities. The semiconductor layer ACT may be made of an oxide semiconductor. In this case, a separate protective layer may be added to protect the oxide semiconductor material, which is vulnerable to external environments such as high temperature.

A gate insulating layer GI is located on the semiconductor layer ACT (e.g., on the channel region C). The gate insulating layer GI may be a single layer or a multilayer containing at least one of silicon nitride (SiNx), silicon oxide (SiO₂), or silicon oxynitride.

A gate electrode GE is arranged on the gate insulating layer GI. The gate electrode GE may be a multilayer stacked metal layer including any one of (e.g., selected from among) copper (Cu), copper alloy, aluminum (AI), aluminum alloy, molybdenum (Mo), and molybdenum alloy.

An interlayer insulating layer IL1 is located on the gate electrode GE and the gate insulating layer GI. The interlayer insulating layer IL1 may include silicon nitride (SiNx), silicon oxide (SiO₂), or silicon oxynitride. The interlayer insulation layer IL1 has openings that expose the source region S and the drain region D, respectively.

A source electrode SE and a drain electrode DE are located on the interlayer insulating layer IL1. The source electrode SE and drain electrode DE are respectively connected to the source region S and drain region D of the semiconductor layer ACT through the openings formed in the interlayer insulating layer IL1.

A passivation layer IL2 is located on the interlayer insulating layer IL1, the source electrode SE, and the drain electrode DE. The passivation layer IL2 covers and flattens the interlayer insulating layer IL1, the source electrode SE, and the drain electrode DE, so that the first electrodes E1a, E1b, and E1c can be formed on the passivation layer IL2 without steps (i.e., allowing the first electrodes E1a, E1b, and E1c to be formed on a smooth surface without any irregularities). This passivation layer IL2 may be made of an organic material such as a polyacrylate resin and/or a polyimide resin, or have a laminated layer structure of an organic material and an inorganic material.

First electrodes E1a, E1b, and E1c are located on the passivation layer IL2. The first electrodes E1a, E1b, and E1c are electrically connected to the drain electrode DE (e.g., a respective drain electrode DE) through an opening in the protective layer IL2.

The driving transistor including a gate electrode GE, a semiconductor layer ACT, a source electrode SE, and a drain electrode DE is connected to a respective first electrode E1a, E1b, or E1c, supplying driving current to each light emitting element ED1, ED2, and ED3. In addition to the driving transistor shown in FIG. 1, the display device according to the present embodiment includes a switching transistor connected to a data line and transmitting a data voltage in response to a scan signal, and a switching transistor connected to the driving transistor and driven in response to the scan signal. The display device may further include a compensation transistor that compensates for the threshold voltage of the transistor.

A partition PDL is located on the passivation layer IL2 and the first electrodes E1a, E1b, and E1c. The partition PDL may have pixel openings OP1, OP2, and OP3 that overlap the first electrodes E1a, E1b, and E1c and define a light emitting region. The partition PDL may contain an organic material such as a polyacrylate resin and/or a polyimide resin, or a silica-based inorganic material. The pixel openings OP1, OP2, and OP3 may have a planar shape substantially similar to the first electrode E1a, E1b, and E1c, and may have a rhombus or octagonal shape similar to a rhombus on the plane, but the present disclosure is not limited to this and the pixel openings OP1, OP2, and OP3 can have any shape such as a rectangle, polygon, and/or the like.

According to one or more embodiments, the first light emitting element ED1 may overlap with the blue light emitting region BLA, the second light emitting element ED2 may overlap with the red light emitting region RLA, and the third light emitting element ED3 may overlap with the green light emitting region GLA.

The first light emitting element ED1 includes a first electrode E1a, a first hole injection layer HIL1, a first hole transport layer HTL1, a first light emitting layer EML1, a first electron transport layer ETL1, and a second electrode E2.

The second light emitting element ED2 includes a first electrode E1b, a second hole injection layer HIL2, a second hole transport layer HTL2, a second light emitting layer EML2, a second electron transport layer ETL2, and a second electrode E2.

The third light emitting element ED3 includes a first electrode E1c, a third hole injection layer HIL3, a third hole transport layer HTL3, a third light emitting layer EML3, a third electron transport layer ETL3, and a second electrode E2.

The partition PDL may be located between the blue light emission region BLA, red light emission region RLA, and green light emission region GLA. That is, the partition PDL may be located between two adjacent light emitting regions selected from among the blue light emission region BLA, the red light emission region RLA, and the green light emission region GLA. The partition PDL has a first opening OP1 overlapping with the blue light emitting region BLA, a second opening OP2 overlapping with the red light emitting region RLA, and a third opening overlapping with the green light emitting region GLA OP3.

The first opening OP1 and the first electrode E1a of the first light emitting element ED1 may overlap, and the second opening OP2 and the first electrode E1b of the second light emitting element ED2 may overlap, and the third opening OP3 and the first electrode E1c of the third light emitting element ED3 may overlap. At least a portion of the first electrode E1a of the first light emitting element ED1, a portion of the first electrode E1b of the second light emitting element ED2, and a portion of the first electrode E1c of the third light emitting element ED3 may overlap with the partition PDL. With respect to the partition PDL, the first electrode E1a of the first light emitting element ED1, the first electrode E1b of the second light emitting element ED2, and the first electrode E1c of the third light emitting element ED3 may be spaced and/or apart (e.g., spaced apart or separated) from each other (e.g., with the partition PDL therebetween).

The first hole injection layer HIL1 is located on the first electrode E1a of the first light emitting element ED1, the second hole injection layer HIL2 is located on the first electrode E1b of the second light emitting element ED2, and the third hole injection layer HIL3 is located on the first electrode E1c of the third light emitting element ED3. The first hole injection layer HIL1, the second hole injection layer HIL2, and the third hole injection layer HIL3 may be spaced and/or apart (e.g., spaced apart or separated) from each other with respect to (e.g., by) the partition PDL. The first hole injection layer HIL1 is located in the first opening OP1, the second hole injection layer HIL2 is located in the second opening OP2, and the third hole injection layer HIL3 is located in the third opening OP3 (e.g., the first, second and third hole injection layers may be located within the respective first, second and third openings).

Each of the first hole injection layer HIL1, the second hole injection layer HIL2, and the third hole injection layer HIL3 may be formed through an inkjet process. The first hole injection layer HIL1, the second hole injection layer HIL2, and the third hole injection layer HIL3 may include the same material, but the present disclosure is not limited thereto and these hole injection layers may include different materials.

Each of the first hole injection layer HIL1, the second hole injection layer HIL2, and the third hole injection layer HIL3 may include a hole injection material. Hole injection materials may include one or more phthalocyanine compounds such as copper phthalocyanine; DNTPD (N,N′-diphenyl-N,N′-bis-[4-(phenyl-m-tolyl-amino)-phenyl]-biphenyl-4,4′-diamine), m-MTDATA (4,4′,4″-[tris(3-methylphenyl)phenylamino]triphenylamine), TDATA (4,4′4\″-Tris (N,N-diphenylamino)triphenylamine), 2-TNATA (4,4′,4″-tris {N,-(2-naphthyl)-N-phenylamino}-triphenylamine), PEDOT/PSS (Poly(3,4-ethylenedioxythiophene)/Poly(4-styrenesulfonate)), PANI/DBSA (Polyaniline/Dodecylbenzenesulfonic acid), PANI/CSA (Polyaniline/Camphor sulfonic acid), PANI/PSS (Polyaniline/Poly(4-styrene sulfonate)), NPB (N,N′-di(naphthalene-I-yl)-N,N′-diphenyl-benzidine), NPD (N,N′-Di(1-naphthyl)-N,N′-diphenyl-(1,1′-biphenyl)-4,4′-diamine), polyether ketone containing triphenylamine (TPAPEK), 4-Isopropyl-4′-methyldiphenyliodonium [Tetrakis(pentafluorophenyl)borate], HAT-CN (dipyrazino[2,3-f:2′,3′-h] quinoxaline-2,3,6,7,10,11-hexacarbonitrile), and/or the like.

The first hole transport layer HTL1 is located on the first hole injection layer HIL1, the second hole transport layer HTL2 is located on the second hole injection layer HIL2, and the third hole transport layer (HTL3) is located on the third hole injection layer HIL3.

The first hole transport layer HTL1, the second hole transport layer HTL2, and the third hole transport layer HTL3 may be spaced and/or apart (e.g., spaced apart or separated) from each other with respect to the partition PDL. The first hole transport layer HTL1 is located within the first opening OP1, the second hole transport layer HTL2 is located within the second opening OP2, and the third hole transport layer HTL3 may be located within the third opening OP3.

Each of the first hole transport layer HTL1, the second hole transport layer HTL2, and the third hole transport layer HTL3 may be formed through an inkjet process. The first hole transport layer HTL1, the second hole transport layer HTL2, and the third hole transport layer HTL3 may include the same material, but the present disclosure is not limited thereto and these hole transport layers may include different materials.

Each of the first hole transport layer HTL1, the second hole transport layer HTL2, and the third hole transport layer HTL3 may include a hole transport material. The hole transport materials may include, for example, one or more carbazole derivatives such as N-phenylcarbazole, and/or polyvinylcarbazole, fluorene derivatives, triphenylamine derivatives such as TPD (N,N′-bis(3-methylphenyl)-N,N′-diphenyl-[1,1-biphenyl]-4,4′-diamine), TCTA (4,4′,4″-tris(N-carbazolyl)triphenylamine), NPB (N,N′-di(naphthalene-I-yl)-N,N′-diphenyl-benzidine), TAPC (4,4′-cyclohexylidene bis[N,N-bis(4-methylphenyl)benzenamine]), HMTPD (4,4′-bis[N,N′-(3-tolyl)amino]-3,3′-dimethylbiphenyl), mCP (1,3-bis(N-carbazolyl)benzene), CzSi (9-(4-tert-butylphenyl)-3,6-bis(triphenylsilyl)-9H-carbazole), m-MTDATA (4,4′,4″-[tris(3-methylphenyl)phenylamino] triphenylamine), and/or the like.

The first light emitting layer EML1 is located on the first hole transport layer HTL1, the second light emitting layer EML2 is located on the second hole transport layer HTL2, and the third light emitting layer EML3 is located on the third hole transport layer HTL3. The first light emitting layer EML1, the second light emitting layer EML2, and the third light emitting layer EML3 may be spaced and/or apart (e.g., spaced apart or separated) from each other with respect to the partition PDL. The first emitting layer EML1 may be located in the first opening OP1, the second emitting layer EML2 may be located in the second opening OP2, and the third emitting layer EML3 may be located in the third opening OP3.

Each of the first emitting layer EML1, the second emitting layer EML2, and the third emitting layer EML3 may be manufactured through an inkjet process.

The first light emitting layer EML1, the second light emitting layer EML2, and the third light emitting layer EML3 may be to emit light of different colors.

The first light emitting layer EML1 may be to emit blue light. The first light emitting layer EML1 may include an organic material, for example, a low-molecular organic material or a high-molecular organic material such as poly(3,4-ethylenedioxythiophene) (PEDOT) with a molecular weight of 10,000 or more.

The second light emitting layer EML2 may be to emit red light. The second light emitting layer EML2 may include a first quantum dot. The third light emitting layer EML3 may be to emit green light. The third light emitting layer EML3 may include a second quantum dot.

Herein, quantum dots including the first quantum dot and the second quantum dot will be described in more detail.

In this specification, a quantum dot (also referred to as a semiconductor nanocrystal) may include a group II-VI compound, a group III-V compound, a group IV-VI compound, a group IV element or compound, a group I-III-VI compound, a group II-III-VI compound, a group I-II-IV-VI compound, and/or a (e.g., any suitable) combination thereof.

The II-VI group compounds include binary compounds selected from among the group consisting of CdSe, CdTe, ZnS, ZnSe, ZnTe, ZnO, HgS, HgSe, HgTe, MgSe, MgS, and mixtures thereof; a tri-element (e.g., ternary) compound selected from among AglnS, CuInS, CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and mixtures thereof; and a tetraelement (e.g., quaternary) compound selected from among the group consisting of HgZnTeS, CdZnSeS, CdZnSeTe, CdZnSTe, CdHgSeS, CdHgSeTe, CdHgSTe, HgZnSeS, HgZnSeTe, HgZnSTe, and mixtures thereof. The group II-VI compound may further include a group III metal.

The group III-V compounds include binary compounds selected from among the group consisting of GaN, GaP, GaAs, GaSb, AlN, AIP, AlAs, AlSb, InN, InP, InAs, InSb, and mixtures thereof; a ternary compound selected from among the group consisting of GaNP, GaNAs, GaNSb, GaPAs, GaPSb, AlNP, AlNAs, AlNSb, AlPAS, AlPSb, InGaP, InNP, InNAs, InNSb, InPAs, InZnP, InPSb, and mixtures thereof; and a quaternary compound selected from among the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, InZnP, and mixtures thereof can be selected. The group III-V compound may further include a group Il metal (e.g., InZnP).

The group IV-VI compounds include binary compounds selected from among the group consisting of SnS, SnSe, SnTe, PbS, PbSe, PbTe, and mixtures thereof; a ternary compound selected from among the group consisting of SnSeS, SnSeTe, SnSTe, PbSeS, PbSeTe, PbSTe, SnPbS, SnPbSe, SnPbTe, and mixtures thereof; and a quaternary element compound selected from among the group consisting of SnPbSSe, SnPbSeTe, SnPbSTe, and mixtures thereof.

The group IV element or compound includes a monoelement (e.g., single element) compound selected from among the group consisting of Si, Ge, and/or one or more (e.g., any suitable) combinations thereof; and a binary compound selected from among the group consisting of SiC, SiGe, and/or one or more (e.g., any suitable) combinations thereof, but the present disclosure is not limited thereto.

Examples of the group I-III-VI compounds include, but are not limited to, CuInSe₂, CuInS₂, CuInGaSe, and CuInGaS. Examples of the group I-II-IV-VI compounds include, but are not limited to, CuZnSnSe and CuZnSnS. The group IV element or compound includes a single element selected from among the group consisting of Si, Ge, and mixtures thereof; and a binary compound selected from among the group consisting of SiC, SiGe, and mixtures thereof.

The group II-III-VI compounds include ZnGaS, ZnAlS, ZnInS, ZnGaSe, ZnAlSe, ZnInSe, ZnGaTe, ZnAlTe, ZnInTe, ZnGaO, ZnAlO, ZnInO, HgGaS, HgAlS, HgInS, HgGaSe, HgAlSe, HgInSe, HgGaTe, HgAlTe, HgInTe, MgGaS, MgAlS, MgInS, MgGaSe, MgAlSe, MgInSe, and/or one or more (e.g., any suitable) combinations thereof, but the present disclosure is not limited thereto. For example, the group II-III-VI compounds may be selected from among HgInTe, MgGaS, MgAlS, MgInS, MgGaSe, MgAlSe, MgInSe, and/or one or more (e.g., any suitable) combinations thereof.

The group I-II-IV-VI compound may be selected from among CuZnSnSe and CuZnSnS, but the present disclosure is not limited thereto.

In one or more embodiments, the quantum dots may not include (e.g., may exclude) cadmium. Quantum dots may include semiconductor nanocrystals based on group III-V compounds including indium and phosphorus. The group III-V compound may further include zinc. Quantum dots may include semiconductor nanocrystals based on group II-VI compounds including chalcogen elements (e.g., sulfur, selenium, tellurium, and/or one or more (e.g., any suitable) combinations thereof) and zinc.

In quantum dots, the above-described di-element (binary) compound, tri-element (ternary) compound, and/or quaternary compound may exist in the particle at a substantially uniform concentration, or may exist in the same particle with the concentration distribution partially divided into different states (e.g., with a non-uniform concentration). Additionally, one quantum dot may have a core/shell structure among (e.g., surrounding or around) other quantum dots. The interface between the core and the shell may have a concentration gradient in which the concentration of elements present in the shell decreases toward the center of the core.

In one or more embodiments, quantum dots may have a core-shell structure including a core containing the above-described nanocrystals and a shell around (e.g., surrounding) the core. The shell of the quantum dot may serve as a protective layer to maintain semiconductor properties by preventing or reducing chemical denaturation of the core and/or as a charging layer to impart electrophoretic properties to the quantum dot. The shell may be single or multi-layered. The interface between the core and the shell may have a concentration gradient in which the concentration of elements present in the shell decreases toward the center of the core. Examples of the shell of the quantum dot include metal or non-metal oxides, semiconductor compounds, and/or one or more (e.g., any suitable) combinations thereof.

For example, the oxide of the metal or non-metal include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, and/or NiO, a ternary compound such as MgAl₂O₄, CoFe₂O₄, NiFe₂O₄, and/or CoMn₂O₄, and/or the like, but the present disclosure is not limited thereto.

In addition, the semiconductor compounds include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, and/or the like. However, the present disclosure is not limited thereto.

The interface between the core and the shell may have a concentration gradient in which the concentration of elements present in the shell decreases toward the center of the core. Additionally, the semiconductor nanocrystal may have a structure including a single semiconductor nanocrystal core and a multi-layered shell around (e.g., surrounding) it. In one or more embodiments, the multilayer shell can have two or more layers, such as 2, 3, 4, 5, or more layers. Two adjacent layers of the shell may have a single composition or different compositions. In a multilayer shell, each layer can have a composition that changes along the radius of the quantum dot.

Quantum dots may have a full width of half maximum FWHM of the emission wavelength spectrum of about 45 nm or less, for example, about 40 nm or less, or about 30 nm or less, and within these ranges, color purity and/or color reproducibility can be improved. Additionally, because the light emitted through these quantum dots is emitted in all directions, the optical viewing angle can be improved.

The quantum dots may have different energy band gaps between the shell material and the core material. For example, the energy band gap of the shell material may be larger than that of the core material. In one or more embodiments, the energy band gap of the shell material may be smaller than that of the core material. The quantum dots may have a multi-layered shell. In a multilayer shell, the energy band gap of the outer layer may be larger than that of the inner layer (i.e., the layer closer to the core). In a multilayer shell, the energy band gap of the outer layer may be smaller than that of the inner layer.

The absorption/emission wavelengths of quantum dots can be controlled by adjusting their composition and size. The maximum emission peak wavelength of the quantum dot may range from ultraviolet to infrared wavelengths or longer.

Quantum dots may have a quantum efficiency of at least about 10%, such as at least about 30%, at least about 50%, at least about 60%, at least about 70%, at least about 90%, or even at 100%. Quantum dots can have a relatively narrow spectrum. The quantum dots may have a full width at half maximum of the emission wavelength spectrum of, for example, about 50 nm or less, such as about 45 nm or less, about 40 nm or less, or about 30 nm or less.

The quantum dots may have a particle size of about 1 nm or more and about 100 nm or less. The size of a particle refers to the diameter of the particle or the diameter converted by assuming a spherical shape from a two-dimensional image obtained by transmission electron microscope analysis. In other words, the size of a particle refers to its diameter if it is spherical, or the diameter calculated by assuming a spherical shape (for non-spherical particles, such as using the major axis) based on a two-dimensional image obtained through transmission electron microscope analysis. The quantum dots may have a size of from about 1 nm to about 20 nm, such as 2 nm or more, 3 nm or more, or 4 nm or more, and 50 nm or less, 40 nm or less, 30 nm or less, 20 nm or less, 15 nm or less, or 10 nm or less. The shape of the quantum dot is not particularly limited. For example, the shape of the quantum dot may include, but is not limited to, sphere, polyhedron, pyramid, multipod, square, cuboid, nanotube, nanorod, nanowire, nanosheet, and/or a (e.g., any suitable) combination thereof.

Quantum dots are commercially available or can be appropriately or suitably synthesized. The particle size of quantum dots can be controlled or selected relatively freely during colloid synthesis, and the particle size can also be adjusted uniformly (e.g., substantially uniformly).

Quantum dots may include organic ligands (e.g., having hydrophobic and/or hydrophilic moieties). The organic ligand residue may be bound to the surface of the quantum dot. The organic ligand includes RCOOH, RNH₂, (R)₂NH, (R)₃N, RSH, (R)₃PO, (R)₃P, ROH, RCOOR, RPO(OH)₂, RHPOOH, (R)₂POOH, and/or a (e.g., any suitable) combination thereof, where R is each independently a C3 to C40 (e.g., C5 or more and C24 or less) substituted or unsubstituted alkyl group, a substituted or unsubstituted alkenyl group, a substituted or unsubstituted aliphatic hydrocarbon group of C3 to C40, a substituted or unsubstituted aryl group of C6 to C40, a substituted or unsubstituted aromatic hydrocarbon group of C6 to C40 (e.g., C6 or more and C20 or less), and/or a (e.g., any suitable) combination thereof.

Examples of the organic ligand include thiol compounds such as methane thiol, ethane thiol, propane thiol, butane thiol, pentane thiol, hexane thiol, octane thiol, dodecane thiol, hexadecane thiol, octadecane thiol, and/or benzyl thiol; amines such as methane amine, ethane amine, propane amine, butane amine, pentyl amine, hexyl amine, octyl amine, nonyl amine, decyl amine, dodecyl amine, hexadecyl amine, octadecyl amine, dimethyl amine, diethyl amine, dipropyl amine, tributylamine, trioctylamine, and/or the like; carboxylic acid compounds such as methanoic acid, ethanoic acid, propanoic acid, butanoic acid, pentanoic acid, hexanoic acid, heptanoic acid, octanoic acid, dodecanoic acid, hexadecanoic acid, octadecanoic acid, oleic acid, and/or benzoic acid; phosphines such as methyl phosphine, ethyl phosphine, propyl phosphine, butyl phosphine, pentyl phosphine, octyl phosphine, dioctyl phosphine, tributyl phosphine, trioctyl phosphine, and/or the like; phosphine compounds such as methyl phosphine oxide, ethyl phosphine oxide, propyl phosphine oxide, butyl phosphine oxide, pentyl phosphine oxide, tributyl phosphine oxide, octyl phosphine oxide, dioctyl phosphine oxide, and/or a trioctyl phosphine oxide compound or its oxide compound; a diphenyl phosphine and/or triphenyl phosphine compounds or their oxide compounds; a C5 to C20 alkyl phosphonic acids such as hexylphosphinic acid, octylphosphinic acid, dodecanephosphinic acid, tetradecanephosphinic acid, hexadecanephosphinic acid, and/or octadecanephosphinic acid, but the present disclosure is not limited thereto. Quantum dots may include hydrophobic organic ligands alone or in a mixture of one or more types (kinds). The hydrophobic organic ligand may not contain a photopolymerizable residue (e.g., an acrylate group, a methacrylate group, and/or the like.).

Referring again to FIG. 1, the first electron transport layer ETL1 may be located on the first light emitting layer EML1, the second electron transport layer ETL2 may be located on the second light emitting layer EML2, and the third electron transport layer ETL3 may be located on the third light emitting layer EML3. The first electron transport layer ETL1, the second electron transport layer ETL2, and the third electron transport layer ETL3 may be spaced and/or apart (e.g., spaced apart or separated) with respect to the partition PDL. The first electron transport layer ETL1 is located in the first opening OP1, the second electron transport layer ETL2 is located in the second opening OP2, and the third electron transport layer ETL3 is located in the third opening OP3.

The first electron transport layer ETL1, the second electron transport layer ETL2, and the third electron transport layer ETL3 may each be formed through an inkjet process. The second electron transport layer ETL2 and the third electron transport layer ETL3 according to one or more embodiments may include the same electron transport material. The first electron transport layer ETL1 may include an electron transport material different from the second electron transport layer ETL2 and the third electron transport layer ETL3.

The first electron transport layer ETL1 may include an electron transport material and, depending on the embodiment, may include a triazine-based compound or an anthracene-based compound. However, the present disclosure is not limited thereto, and the electron transport material may be (e.g., is), for example, any one selected from among Alq3 (Tris(8-hydroxyquinolinato)aluminum), 1,3,5-tri[(3-pyridyl)-phen-3-yl]benzene, 2,4,6-tris(3′-(pyridin-3-yl) biphenyl-3-yl)-1,3,5-triazine, 2-(4-(N-phenylbenzoimidazolyl-1-ylphenyl)-9,10-dinaphthylanthracene, TPBi (1,3,5-tris(1-phenyl-1H-benzo[d]imidazol-2-yl)benzene), BCP (2,9-dimethyl-4,7-diphenyl-1,10-phenanthroline), Bphen (4,7-diphenyl-1,10-phenanthroline), TAZ (3-(4-biphenylyl)-4-phenyl-5-tert-butylphenyl-1,2,4-triazole), NTAZ (4)-(naphthalen-1-yl)-3,5-diphenyl-4H-1,2,4-triazole), tBu-PBD (2-(4-biphenylyl)-5-(4-tert-butylphenyl)-1, 3,4-oxadiazole), BAlq (bis(2-methyl-8-quinolinolato-N1,O8)-(1,1′-biphenyl-4-olato)aluminum), Bebq2 (berylliumbis(benzoquinolin-10-olate), ADN (9,10-di(naphthalen-2-yl) anthracene), TSPO1 (diphenyl(4-(triphenylsilyl)phenyl)phosphine oxide), TPM-TAZ (2,4,6-tris(3-(pyrimidin-5-yl)phenyl)-1,3,5-triazine), and mixtures (e.g., combinations) thereof. In one or more embodiments, the second electron transport layer ETL2 and the third electron transport layer ETL3 may each include ZnMgO.

The second electrode E2 may be positioned on the first electron transport layer ETL1, the second electron transport layer ETL2, and the third electron transport layer ETL3. The second electrode E2 may be continuously positioned across the blue light emitting region BLA, the red light emitting region RLA, the green light emitting region GLA, and the non-emitting region NLA. The second electrode E2 may receive a common voltage through a common voltage transmitter in the non-display region.

Here, the first electrodes E1a, E1b, and E1c may (e.g., each) be an anode, which is a hole injection electrode, and the second electrode E2 may be a cathode, which is an electron injection electrode. However, one or more embodiments is not necessarily limited to this, and the first electrode(s) E1a, E1b, and/or E1c may serve as cathode(s) and the second electrode(s) E2 may serve as anode(s) depending on the driving method of the display device.

A capping layer CPL may be positioned on the second electrode E2. The capping layer CPL may be continuously positioned across the blue light emitting region BLA, the red light emitting region RLA, the green light emitting region GLA, and non-emitting region NLA.

An encapsulation layer ENC may be located on the capping layer CPL. The encapsulation layer ENC may seal the display layer by covering not only the top surface but also the side surfaces of the display layer including the light emitting elements ED1, ED2, and ED3.

Because the light emitting element is vulnerable (e.g., very vulnerable) to moisture and oxygen, the encapsulation layer ENC seals the display layer and blocks the inflow of external moisture and/or oxygen. The encapsulation layer ENC may include a plurality of layers, and may be formed as a composite layer including both (e.g., simultaneously) an inorganic layer and an organic layer, and may be a triple layer in which a first inorganic layer, an organic layer, and a second inorganic layer are formed sequentially.

Hereinafter, a method of manufacturing a display device according to one or more embodiments will be described with reference to FIG. 1 described above and FIGS. 2 to 10.

First, a plurality of transistors are formed on the substrate, and first electrodes E1a, E1b, and E1c are formed on the passivation layer. In the following drawings, only components located on the first electrodes E1a, E1b, and E1c are shown for convenience. A partition PDL having openings OP1, OP2, and OP3 exposing the first electrodes E1a, E1b, and E1c, respectively, is formed on the first electrodes E1a, E1b, and E1c.

Then, a first ink (e.g., first ink composition) for forming hole injection layers HIL1, HIL2, and HIL3 is discharged into each of the openings OP1, OP2, and OP3 of the partition PDL (S1). Thereafter, the discharged first ink is dried (S2) and baked (S3) to form first to third hole injection layers HIL1, HIL2, and HIL3 as shown in FIG. 3. Although this specification describes the first ink for convenience, each of the first to third hole injection layers HIL1, HIL2, and HIL3 may include the same hole injection material or may include different hole injection materials.

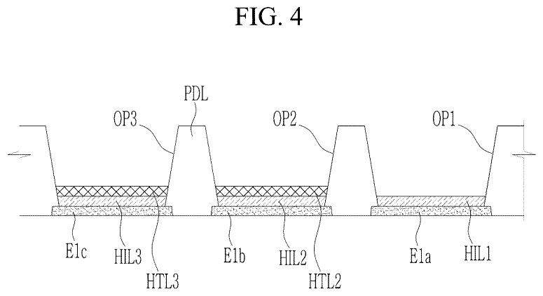

Next, a second ink (e.g., second ink composition) for forming the second and third hole transport layers HTL2 and HTL3 is discharged on the second and third hole injection layers HIL2 and HIL3 (S4). Thereafter, the discharged second ink is dried (S5) and baked (S6) to form second to third hole transport layers HTL2 and HTL3 as shown in FIG. 4. Although this specification describes the second ink for convenience, the second and the third hole transport layers HTL2 and HTL3 may each include the same hole transport material or different hole transport materials. At this time, a hole transport layer is not formed within the first opening OP1.

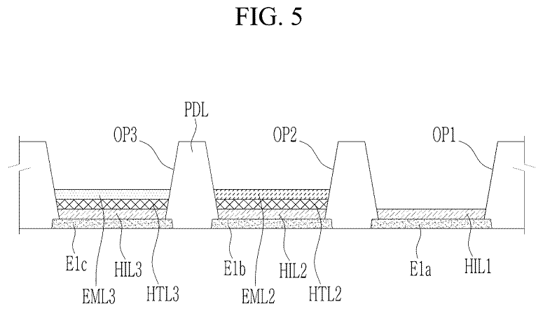

Next, a third ink (e.g., third ink composition) for forming the second and third light emitting layers EML2 and EML3 is discharged on the second and the third hole transport layers HTL2 and HTL3 (S7). Then, the third ink is dried (S8) and baked (S9) to form the second and third light emitting layers EML2 and EML3 as shown in FIG. 5. Although this specification describes the third ink for convenience, the second light emitting layer EML2 can be formed using a 3-1 ink containing first quantum dots (red quantum dots), and the third light emitting layer EML3 can be formed using a 3-2 ink containing second quantum dots (green quantum dots). At this time, a light emitting layer is not formed within the first opening OP1.

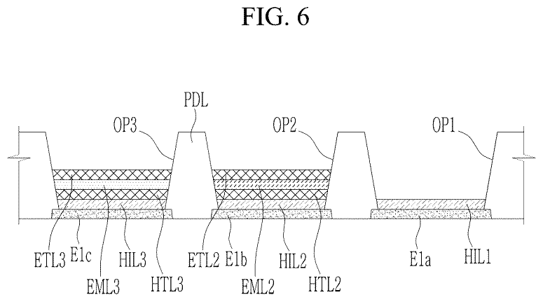

Then, a fourth ink (e.g., fourth ink composition) for forming the second and third electron transport layers ETL2 and ETL3 is discharged on the second and third light emitting layers EML2 and EML3 (S10). The fourth ink is dried (S11) and baked (S12) to form second and third electron transport layers ETL2 and ETL3 as shown in FIG. 6. Although this specification describes the fourth ink for convenience, the second and third electron transport layers ETL2 and ETL3 may include different materials depending on one or more embodiments or may include the same material (including ZnMgO, for example). At this time, an electron transport layer is not formed within the first opening OP1.

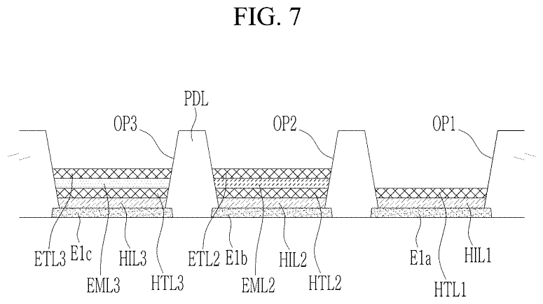

After forming the second electron transport layer ETL2 and the third electron transport layer ETL3 within the second opening OP2 and the third opening OP3, a fifth ink (e.g., fifth ink composition) containing the hole transport material is ejected (e.g., discharged) within the first opening OP1 (S13). Then, the fifth ink is dried (S14) and baked (S15) to form a first hole transport layer HTL1 on the first hole injection layer HIL1 as shown in FIG. 7.

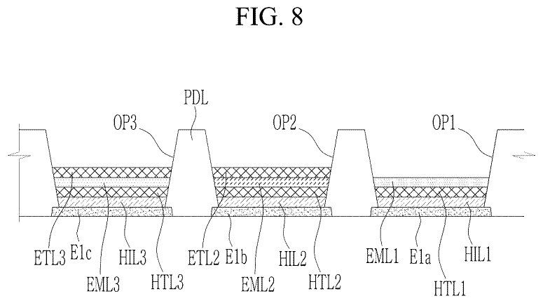

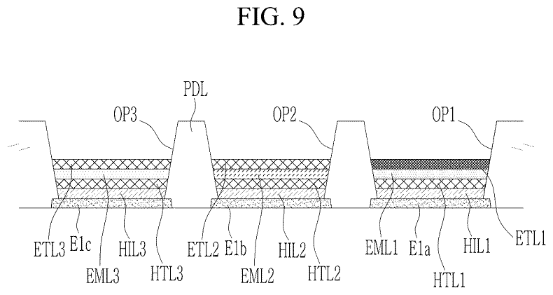

Next, a sixth ink (e.g., sixth ink composition) containing a blue light emitting material is discharged onto the first hole transport layer HTL1 (S16). Then, the sixth ink is dried (S17) and baked (S18) to form the first light emitting layer EML1 located on the first hole transport layer HTL1, as shown in FIG. 8. Next, a seventh ink (e.g., seventh ink composition) containing the first electron transport material is discharged onto the first emitting layer EML1 (S19). Then, the seventh ink is dried (S20) and baked (S21) to form a first electron transport layer ETL1 located on the first light emitting layer EML1, as shown in FIG. 9. At this time, the first electron transport layer ETL1 may include an electron transport material different from the second electron transport layer ETL2 and the third electron transport layer ETL3. As an example, the second electron transport layer ETL2 and the third electron transport layer ETL3 may include an inorganic electron transport material, and the first electron transport layer ETL1 may include an organic electron transport material.

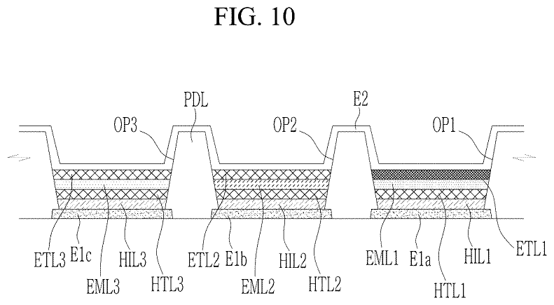

Then, as shown in FIG. 10, the second electrode E2 is deposited to overlap substantially the entire surface of the substrate SUB (S22). The second electrode E2 may be continuously deposited over substantially the entire surface of the substrate SUB. The second electrode E2 may continuously overlap the first emitting layer EML1, the second emitting layer EML2, and the third emitting layer EML3.

Afterwards, an encapsulation layer ENC is formed on the second electrode E2 to manufacture a display device having the structure shown in FIG. 1.

According to the manufacturing method of the display device according to one or more embodiments, after manufacturing a second electron transport layer of the second light emitting element and the third electron transport layer of the third light emitting element, the subsequent structure including the first hole transport layer of the first light emitting element is stacked (sequentially deposited). As in one or more embodiments, if (e.g., when) the first light emitting layer includes an organic polymer material and the second and third light emitting layers include quantum dots, scattering (or cross-contamination) may be generated on the surface of each layer between adjacent light-emitting regions (RLA, GLA, and BLA), and alternatively, there may be a problem that the characteristics of the light emitting element are impaired by the dissolved surface (e.g., dissolved by the composition for an adjacent light emitting layer). For example, this problem of surface property deterioration occurs at the interface between the hole transport layer and the light emitting layer. In other words, if the first light-emitting layer includes an organic polymer material and the second and third light-emitting layers include quantum dots, scattering (or cross-contamination) may occur on the surface of each layer between adjacent light-emitting regions (RLA, GLA, and BLA). Additionally, the characteristics of the light-emitting element may be impaired by the dissolved surface (e.g., dissolved by the composition for an adjacent light-emitting layer). This issue of surface property deterioration particularly occurs at the interface between the hole transport layer and the light-emitting layer.

However, according to one or more embodiments, the first light emitting element including an organic polymer material is manufactured after the second light emitting element and the third light emitting element including quantum dots are manufactured first, thereby minimizing or reducing the impact due to dissolution and/or scattering on the surface, thereby providing a light emitting element with improved reliability. That is, in one or more embodiments, the first light-emitting element, which includes an organic polymer material, is manufactured after the second and third light-emitting elements, which include quantum dots. This sequence minimizes or reduces the impact of dissolution and/or scattering on the surface, thereby enhancing the reliability of the light-emitting element.

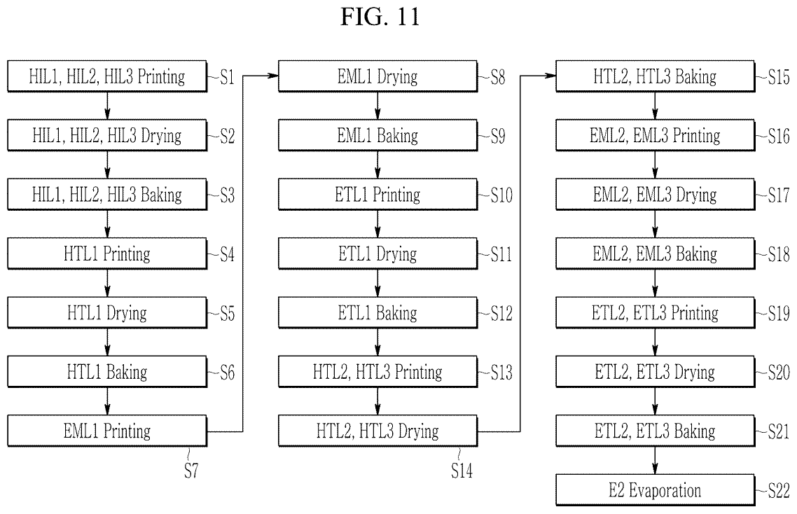

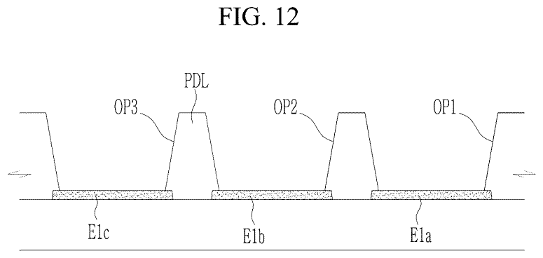

Hereinafter, a method of manufacturing a display device according to one or more embodiments will be described with reference to FIGS. 11 to 20. FIG. 11 is a flowchart of a method of manufacturing some components of a display device according to one or more embodiments, and FIGS. 12 to 20 are cross-sectional views of a manufacturing process of a display device according to one or more embodiments.

Hereinafter, a method of manufacturing a display device according to one or more embodiments will be described with reference to FIGS. 11 to 20 along with FIG. 1. Descriptions of components that are the same as those described above will not be provided.

As shown in FIG. 12, the partition PDL having openings OP1, OP2, and OP3 exposing the first electrodes E1a, E1b, and E1c, respectively, is formed on the first electrodes E1a, E1b, and E1c.

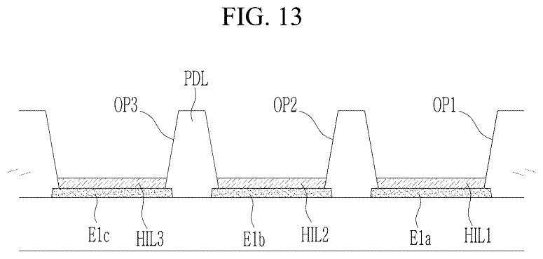

Then, as shown in FIG. 13, the first ink for forming hole injection layers HIL1, HIL2, and HIL3 is discharged into each of the openings OP1, OP2, and OP3 of the partition PDL (S1). Thereafter, the discharged first ink is dried (S2) and baked (S3) to form first to third hole injection layers HIL1, HIL2, and HIL3 as shown in FIG. 13. Although this specification describes the first ink for convenience, each of the first to third hole injection layers HIL1, HIL2, and HIL3 may include the same hole injection material or may include different hole injection materials.

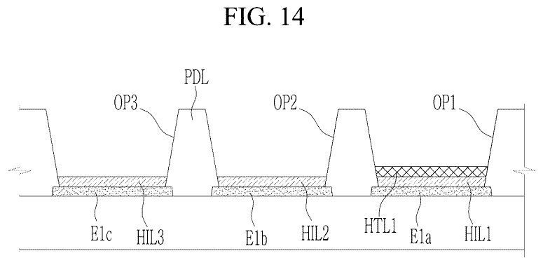

Next, the fifth ink containing a hole transport material is discharged into the first opening OP1 (S4). Then, the fifth ink is dried (S5) and baked (S6) to form a first hole transport layer HTL1 on the first hole injection layer HIL1 as shown in FIG. 14. At this time, a hole transport layer is not formed in the second opening OP2 and the third opening OP3.

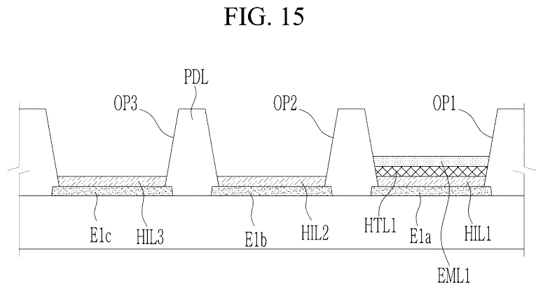

Next, the sixth ink containing a blue light emitting material is discharged onto the first hole transport layer HTL1 (S7). Then, the sixth ink is dried (S8) and baked (S9) to form the first light emitting layer EML1 located on the first hole transport layer HTL1, as shown in FIG. 15. At this time, a light emitting layer is not formed in the second opening OP2 and the third opening OP3.

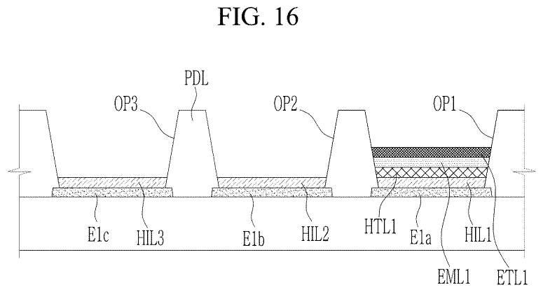

Next, the seventh ink containing the first electron transport material is discharged onto the first emitting layer EML1 (S10). Then, the seventh ink is dried (S11) and baked (S12) to form a first electron transport layer ETL1 located on the first light emitting layer EML1, as shown in FIG. 16. At this time, a electron transport layer is not formed in the second opening OP2 and the third opening OP3.

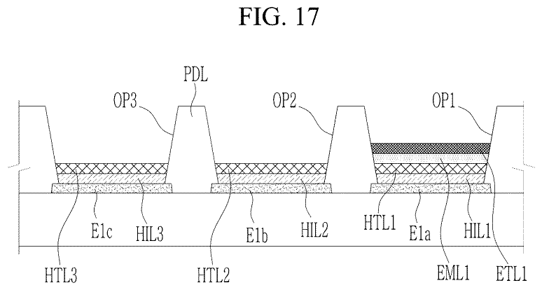

Thereafter, the second ink for forming the second to third hole transport layers HTL2 and HTL3 is discharged on the second and third hole injection layers HIL2 and HIL3 (S13). Thereafter, the discharged second ink is dried (S14) and baked (S15) to form second to third hole transport layers HTL2 and HTL3 as shown in FIG. 17. Although this specification describes the second ink for convenience, the second and the third hole transport layers HTL2 and HTL3 may each include the same hole transport material or different hole transport materials.

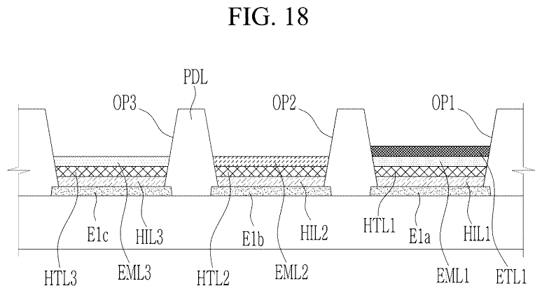

Next, the third ink for forming the second and third light emitting layers EML2 and EML3 is discharged on the second and the third hole transport layers HTL2 and HTL3 (S16). Then, the third ink is dried (S17) and baked (S18) to form the second and third light emitting layers EML2 and EML3 as shown in FIG. 18. Although this specification describes the third ink for convenience, the second light emitting layer EML2 can be formed using the 3-1 ink containing the first quantum dots (red quantum dots), and the third light emitting layer EML3 can be formed using the 3-2 ink containing the second quantum dots (green quantum dots).

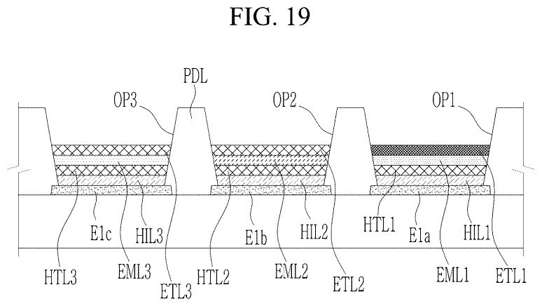

Then, the fourth ink for forming the second and third electron transport layers ETL2 and ETL3 is discharged on the second and third light emitting layers EML2 and EML3 (S19). The fourth ink is dried (S20) and baked (S21) to form second and third electron transport layers ETL2 and ETL3 as shown in FIG. 19. Although this specification describes the fourth ink for convenience, the second and third electron transport layers ETL2 and ETL3 may include different materials depending on one or more embodiments or may include the same material (including ZnMgO, for example). At this time, the first electron transport layer ETL1 may include an electron transport material different from the second electron transport layer ETL2 and the third electron transport layer ETL3. As an example, the second electron transport layer ETL2 and the third electron transport layer ETL3 may include an inorganic electron transport material, and the first electron transport layer ETL1 may include an organic electron transport material.

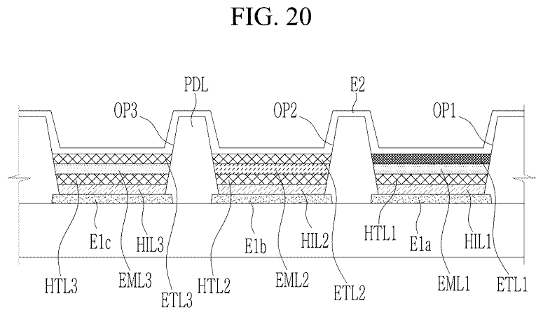

Then, as shown in FIG. 20, the second electrode E2 is deposited to overlap substantially the entire surface of the substrate SUB (S22). The second electrode E2 may be continuously deposited over substantially the entire surface of the substrate SUB. The second electrode E2 may continuously overlap the first emitting layer EML1, the second emitting layer EML2, and the third emitting layer EML3. Afterwards, an encapsulation layer ENC is formed on the second electrode E2 to manufacture a display device having the structure shown in FIG. 1.

According to the manufacturing method of the display device according to one or more embodiments, after manufacturing layers up to the first electron transport layer of the first light emitting element, subsequent structures including the second hole transport layer of the second light emitting element and the third hole transport layer of the third light emitting element are stacked (e.g., sequentially deposited). As in one or more embodiments, if (e.g., when) the first light emitting layer includes an organic polymer material and the second and third light emitting layers include quantum dots, scattering (or cross-contamination) generated on the surface of each layer is between adjacent light-emitting regions RLA, GLA, and BLA, and alternatively, there is a problem that the characteristics of the light emitting element are impaired by the dissolved surface (e.g., dissolved by the composition for an adjacent light emitting layer). For example, this problem of surface property deterioration occurs at the interface between the hole transport layer and the light emitting layer.

However, according to one or more embodiments, the first light emitting element including an organic polymer material is first manufactured, and then the second and third light emitting elements including quantum dots are manufactured. Therefore, exposure of the interface between the hole transport layer and the light emitting layer, which are formed of different materials, can be minimized or reduced. Therefore, it is possible to provide a light emitting element with improved reliability by minimizing or reducing the effects of dissolution and/or scattering on the surface of the hole transport layer.

As utilized herein, the singular forms “a,” “an,” “one,” and “the” are intended to include the plural forms as well, unless the context clearly indicates otherwise. The use of “may” when describing embodiments of the inventive concept refers to “one or more embodiments of the inventive concept.”

As used herein, the terms “use,” “using,” and “used” may be considered synonymous with the terms “utilize,” “utilizing,” and “utilized,” respectively. As used herein, expressions such as “at least one of”, “one of”, and “selected from”, when preceding a list of elements, modify the entire list of elements and do not modify the individual elements of the list. For example, “at least one selected from among a, b and c”, “at least one of a, b or c”, and “at least one of a, b and/or c” may indicate only a, only b, only c, both (e.g., simultaneously) a and b, both (e.g., simultaneously) a and c, both (e.g., simultaneously) b and c, all of a, b, and c, or variations thereof.

In the present disclosure, when dots, particles, dot particles, and/or the like, are spherical, “diameter” or “particle size” indicates a particle diameter or an average particle diameter, and when the particles are non-spherical, the “diameter” or “particle size” indicates a major axis length or an average major axis length. The diameter (or size) of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter (or size) is referred to as D50. D50 refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

As used herein, the term “substantially,” “about,” and similar terms are used as terms of approximation and not as terms of degree, and are intended to account for the inherent deviations in measured or calculated values that would be recognized by those of ordinary skill in the art. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within +30%, 20%, 10%, 5% of the stated value.

Also, any numerical range recited herein is intended to include all subranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Here, unless otherwise defined, the listing of steps, tasks, or acts in a particular order should not necessarily mean that the invention or claims require that particular order. That is, the general rule that unless the steps, tasks, or acts of a method (e.g., a method claim) actually recite an order, the steps, tasks, or acts should not be construed to require one.

A display manufacturing device, a display device, and/or any other relevant devices or components according to embodiments of the present invention described herein may be implemented utilizing any suitable hardware, firmware (e.g. an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the present disclosure.

A person of ordinary skill in the art, in view of the present disclosure in its entirety, would appreciate that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Although one or more embodiments of the present disclosure have been described in more detail above, the scope of the present disclosure is not limited thereto, and one or more suitable modifications and improvements can be made by those skilled in the art using the basic concepts of the present disclosure defined in the following claims and equivalents thereof.

### REFERENCE NUMERALS

E1a, E1b, E1c: first electrode
HIL1, HIL2, HIL3: hole injection layer
HTL1, HTL2, HTL3: hole transport layer
EML1, EML2, EML3: light emitting layer
ETL1, ETL2, ETL3: electron transport layer
E2: second electrode

What is claimed is:

1. A method comprising:
forming a plurality of first electrodes on a substrate;
forming a first hole injection layer, a second hole injection layer, and a third hole injection layer on a respective one of the plurality of first electrodes;
forming a second hole transport layer and a third hole transport layer respectively on the second hole injection layer and the third hole injection layer;
forming a second light emitting layer and a third light emitting layer respectively on the second hole transport layer and the third hole transport layer; and
after the forming of the second light emitting layer and the third light emitting layer, sequentially forming a first hole transport layer and a first light emitting layer on the first hole injection layer,
wherein each of the second light emitting layer and the third light emitting layer comprises a quantum dot, and
the first light emitting layer comprises an organic material, and
wherein the method is a method of manufacturing a display device.

2. The method of claim 1, further comprising:
after the forming of the second light emitting layer and the third light emitting layer, forming a second electron transport layer and a third electron transport layer respectively on the second light emitting layer and the third light emitting layer.

3. The method of claim 2, wherein:
the first hole transport layer and the first light emitting layer are sequentially formed after the forming of the second electron transport layer and the third electron transport layer.

4. The method of claim 3, further comprising:
forming a first electron transport layer on the first light emitting layer.

5. The method of claim 1, wherein:
the display device comprises:
a blue light emitting region overlapping with the first light emitting layer,
a red light emitting region overlapping with the second light emitting layer, and
a green light emitting region overlapping with the third light emitting layer, and
the method further comprising forming a partition between adjacent light emitting regions selected from among the blue light emitting region, the red light emitting region, and the green light emitting region.

6. The method of claim 5, wherein:
the first hole injection layer, the second hole injection layer, and the third hole injection layer are spaced from each other with respect to the partition, and
the first hole transport layer, the second hole transport layer, and the third hole transport layer are spaced from each other with respect to the partition.

7. The method of claim 5, further comprising:
forming a second electrode continuously positioned on the first light emitting layer, the second light emitting layer, and the third light emitting layer.

8. The method of claim 1, wherein:
the organic material of the first light emitting layer comprises an organic polymer material,
the quantum dot of the second light emitting layer comprises a red quantum dot, and
the quantum dot of the third light emitting layer comprises a green quantum dot.

9. The method of claim 4, wherein:
the second electron transport layer and the third electron transport layer each comprise ZnMgO.

10. The method of claim 9, wherein:
the first electron transport layer comprises an organic electron transport material.

11. A method comprising:
forming a plurality of first electrodes on a substrate,
forming a first hole injection layer, a second hole injection layer, and a third hole injection layer on a respective one of the plurality of first electrodes, forming a first hole transport layer on the first hole injection layer,
forming a first light emitting layer on the first hole transport layer,
after the forming of the first light emitting layer, forming a second hole transport layer and a third hole transport layer respectively on the second hole injection layer and the third hole injection layer, and
forming a second light emitting layer and a third light emitting layer respectively on the second hole transport layer and the third hole transport layer,
wherein the method is a method of manufacturing a display device.

12. The method of claim 11, further comprising:
after the forming of the first light emitting layer, forming a first electron transport layer on the first light emitting layer.

13. The method of claim 12, wherein:
the forming of the second hole transport layer and the third hole transport layer is after the forming of the first electron transport layer.

14. The method of claim 13, further comprising:
forming a second electron transport layer and a third electron transport layer respectively on the second light emitting layer and the third light emitting layer.

15. The method of claim 14, further comprising:
forming a second electrode continuously positioned on the first electron transport layer, the second electron transport layer, and the third electron transport layer.

16. The method of claim 11, wherein:
the display device comprises:
a blue light emitting region overlapping with the first light emitting layer,
a red light emitting region overlapping with the second light emitting layer, and
a green light emitting region overlapping with the third light emitting layer, and
the method further comprising:
forming a partition between adjacent light emitting regions selected from among the blue light emitting region, the red light emitting region, and the green light emitting region.

17. The method of claim 16, wherein:
the first hole injection layer, the second hole injection layer, and the third hole injection layer are spaced from each other with respect to the partition, and
the first hole transport layer, the second hole transport layer, and the third hole transport layer are spaced from each other with respect to the partition.

18. The method of claim 11, wherein:
the first light emitting layer comprises an organic material,
the second light emitting layer comprises a first quantum dot, and
the third light emitting layer comprises a second quantum dot.

19. The method of claim 14, wherein:
the second electron transport layer and the third electron transport layer each comprise ZnMgO.

20. The method of claim 19, wherein:
the first electron transport layer comprises an organic electron transport material.
